(19) United States
(12) Patent Application Publication
(10) Pub. No.: US 2026/0246357 A1
(43) Pub. Date: Aug. 20, 2026

(54) POWER CONVERTER INTEGRATED CIRCUIT WITH CONNECTION FAULT DETECTION FUNCTION

(71) Applicant: Chengdu Monolithic Power Systems Co., Ltd., Chengdu (CN)

(72) Inventors: Hsin Chen, New Taipei City (TW); Wei-Heng Wang, New Taipei City (TW); Yong Deng, Chengdu (CN); Haitang Wang, Chengdu (CN); Pengjie Lai, Cupertino, CA (US)

(21) Appl. No.: 19/540,352

(22) Filed: Feb. 13, 2026

(30) Foreign Application Priority Data
Feb. 17, 2025 (CN) 202510170379.9

(51) Int. Cl. H02M 1/00; H02M 1/08; H02M 3/158

(52) U.S. Cl. CPC H02M 1/0009; H02M 1/08; H02M 3/1588

(57) ABSTRACT

An integrated circuit for a power conversion circuit includes: an input terminal, an output terminal, a reference ground terminal, a switching terminal, and an abnormal connection event detection circuit. The input terminal is configured to receive an input voltage. The output terminal is configured to provide an output voltage. The reference ground terminal is configured to be coupled to a reference ground voltage. The switching terminal is configured to be coupled at a common connection node of a high-side switch and a low-side switch, wherein the high-side switch and the low-side switch are coupled in series between the input terminal and the reference ground terminal. The abnormal connection event detection circuit is configured to detect an abnormal connection event in the power conversion circuit before the startup of the power conversion circuit, and generate an abnormal connection warning signal for indicating the abnormal connection event based on detecting that the abnormal connection event occurs.

### CROSS-REFERENCE

The present application claims priority to, and the benefit of, Chinese application No. 202510170379.9 filed on Feb. 17, 2025, which is incorporated herein by reference in its entirety.

### TECHNICAL FIELD

The present application relates to DC/DC power converters, and more particularly to fault self-detection circuits and methods for protecting circuit components from abnormal connections.

### BACKGROUND

Generally, a switching conversion circuit may leverage characteristics of an energy storage element such as a capacitor or an inductor. By controlling the operation of controllable power switches (e.g., metal-oxide-semiconductor field-effect transistors, MOSFETs) through control signals (e.g., pulse-width modulation (PWM) signals) to switch them on or off at high frequency, these circuits enable the storage components to alternately store and release electrical energy. Through the process of energy flow, the power converter can convert the input voltage into another stable voltage to supply power to various application devices.

In a soldering process of a power management system, it is crucial to ensure accurate soldering of related power devices (for example, a power switch and a power inductor, etc.) in a power converter. Therefore, an effective fault detection scheme must be established to identify abnormal connections such as short circuits or cold solder joints in power devices, thereby guaranteeing the performance and reliability of the power management system.

### SUMMARY

Based on the above problems, the present disclosure provides an integrated circuit for a power conversion circuit, including: an input terminal, an output terminal, a reference ground terminal, a switching terminal and an abnormal connection event detection circuit. The input terminal is configured to receive an input voltage. The output terminal is configured to provide an output voltage. The reference ground terminal is configured to be coupled to a reference ground voltage. The switching terminal is configured to be coupled to a common connection node of the high-side switch and the low-side switch. Wherein the high-side switch and the low-side switch are coupled in series between the output terminal and the reference ground terminal. The abnormal connection event detection circuit is configured to detect an abnormal connection event in the power conversion circuit before the startup of the power conversion circuit, and generate an abnormal connection warning signal for indicating the abnormal connection event based on detecting that the abnormal connection event occurs.

### BRIEF DESCRIPTION OF DRAWINGS

To describe the technical method in the embodiments of the present invention more clearly, the drawings required for describing the embodiments or the prior art will be introduced briefly. Obviously, the drawings described below are merely some embodiments of the present invention. For those skilled in the art, other drawings may be obtained based on these drawings without creative labor.

FIG. 1 illustrates a block diagram of a power management system 100 according to an embodiment of the present invention.

FIG. 2 illustrates an exemplary circuit diagram of a power stage 200 of a power converter in the power management system shown in FIG. 1.

FIG. 3 illustrates a flowchart of a method 300 for detecting an abnormal connection event according to an embodiment of the present invention.

FIG. 4A illustrates a schematic diagram of a circuit for determining whether an HS short-circuit event has occurred in method 300.

FIG. 4B illustrates a schematic diagram of a circuit for determining whether an LS short-circuit event or an L open-circuit event has occurred in method 300.

FIG. 5 illustrates a flowchart of a method 500 for detecting an abnormal connection event according to an embodiment of the present invention.

FIG. 6A illustrates a schematic diagram of a circuit for determining whether an HS short-circuit event has occurred in method 500.

FIG. 6B illustrates a schematic diagram of a circuit for determining whether an LS short-circuit event has occurred in method 500.

FIG. 6C illustrates a schematic diagram of a circuit for determining whether an L open-circuit event has occurred in method 500.

FIG. 7 illustrates a flowchart of a method 700 for detecting an abnormal connection event according to an embodiment of the present invention.

FIG. 8A illustrates a schematic diagram of a circuit for determining whether an HS short-circuit event has occurred in method 700.

FIG. 8B illustrates a schematic diagram of a circuit for determining whether an LS short-circuit event has occurred in method 700.

FIG. 8C illustrates a schematic diagram of a circuit for determining whether an L open-circuit event has occurred in method 700.

### DETAILED DESCRIPTION

Various embodiments of the present invention will now be described. In the following description, certain specific details are included, such as exemplary circuits and exemplary values for these circuit components, to provide a thorough understanding of the embodiments. However, one skilled in the relevant art will recognize, that the disclosure can be performed without one or more of the specific details, or with other methods, components, materials, etc. In other instances, well-known structures, materials, processes or operations are not shown or described in detail to avoid obscuring aspects of the disclosure.

Throughout the specification and claims, the phrases “in an embodiment,” “in some embodiments,” “in an implementation,” and “in some implementations” used include combinations and sub-combinations of the various features described herein, as well as variations and modifications thereof. These phrases used herein do not necessarily refer to the same embodiment, although they may. It will be understood by those skilled in the art that the meanings of the above terms do not necessarily limit the terms, but merely provide illustrative examples for the terms. Note that when a component is “connected to” or “coupled to” another component, this means that the component is directly connected to or coupled to the other component, or indirectly connected to or coupled to the other component via another component. Particular features, structures or characteristics may be included in an integrated circuit, an electronic circuit, a combinational logic circuit or other suitable components that provide the described functionality. Furthermore, it should be understood that the drawings provided herewith are for explanation purposes to those of ordinary skill in the art and the drawings are not necessarily drawn to scale.

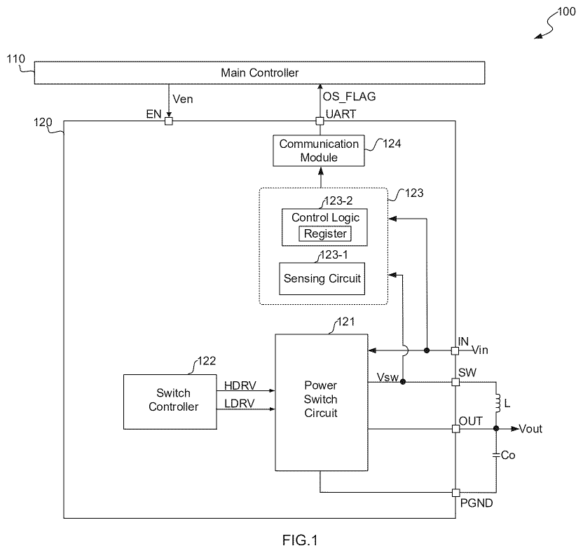

FIG. 1 is a block diagram illustrating a power management system 100 according to an embodiment of the present invention. Referring to FIG. 1, the power management system 100 includes a power converter 120 and a main controller 110.

As shown in FIG. 1, the power converter 120 includes a power switch circuit 121, a switch controller 122, and an abnormal connection event detection circuit 123. In addition, the power converter 120 further includes connection terminals including: an input terminal IN, an output terminal OUT, a switching terminal SW, an enable terminal EN, a communication terminal UART, and a reference ground terminal PGND. For simplicity of description, other unrelated circuit components and terminals are omitted herein.

The switching terminal SW is configured to be coupled to one end of a power inductor L, and the output terminal OUT is configured to be coupled to the other end of the power inductor L. The switching component in the power switch circuit 121 is configured to be turned on or off under the control of a driving signal(s) (e.g., a pair of signals HDRV and LDRV shown as opposite logic states in the drawing) to increase or decrease an inductor current flowing through the power inductor L, thereby converting an input voltage Vin into an output voltage Vout. The output terminal OUT is configured to provide the output voltage Vout. An output capacitor Co is coupled between the output terminal OUT and the reference ground terminal PGND for filtering and smoothing the output voltage Vout. Hereinafter, the power switch circuit 121 and the power inductor L and the output capacitor Co are referred to as a power stage.

The switch controller 122 may generate a switch driving signal(s) based on a feedback signal representative of the output voltage Vout of the power converter 120. For example, in an embodiment of a PWM control method such as voltage control and current control, the switch controller 122 may amplify a difference between the feedback signal and a reference signal, and then compare the amplified difference signal with a ramp signal, to generate the switch driving signal(s). It should be understood that the switch controller 122 may be implemented in any suitable control mode and circuit structure, as long as it can control the power switch circuit 121. A topology structure and a control mode of the switch controller 122 are not limited in the present invention.

In an embodiment, the abnormal connection event detection circuit 123, the switch controller 122 and the power switch circuit 121 may be embedded in a power management integrated circuit (PMIC). It should be understood that the packaging form of the power converter 120 is not limited in the present disclosure. For example, in another embodiment, the power switch circuit 121 may be disposed outside the PMIC.

In an embodiment, the abnormal connection event detection circuit 123 is configured to be enabled in response to the PMIC being powered on (e.g., receiving the input voltage Vin), and to determine whether an abnormal connection event occurs in the power switch circuit 121 based on power stage signals received from the power switch circuit 121, and generate an abnormal connection warning signal OS_FLAG. For example, the power stage signals here may include the voltage Vsw on the common connection node (or the switching terminal SW) of the switching transistors in the power switching circuit 121 or the output voltage Vout on the output terminal OUT.

As shown, the abnormal connection event detection circuit 123 includes a sensing circuit 123-1 for sensing the power stage signals and a control logic circuit 123-2 for controlling the abnormal connection event detection process. In addition, the abnormal connection event detection circuit 123 may further include a register dedicated to recording the abnormal connection event. When it is determined that the abnormal connection event occurs, a bit value of the register may be set to a first value (for example, 1).

In an embodiment, the power converter 120 may further include a communication module 124 for transmitting the abnormal connection warning signal OS_FLAG to the external main controller 110 (e.g., via the communication terminal UART) in response to the bit value in the abnormal connection event register being set to the first value. The communication protocols supported by the communication module 124 includes, but is not limited to, a Universal Asynchronous Receiver-Transmitter (UART) protocol, a Serial Peripheral Interface (SPI) protocol, and an Inter-Integrated Circuit (I2C) protocol.

In response to the abnormal connection warning signal OS_FLAG not received from the power converter 120 (i.e., an abnormal connection event is not detected by the abnormal connection event detection circuit 123), the main controller 110 generates a corresponding enable signal Ven (e.g., a signal in an enable logic state (or logic high)) and sends the enable signal Ven to the enable terminal EN. This enables the PMIC when no abnormal connection event is detected, thereby initiating a startup process (e.g., soft start) of the PMIC. Thus, through the internally configured fault self-detection function, connection faults can be promptly detected before the PMIC starts up (i.e., before the PMIC receives the enable signal Ven via the enable terminal EN), and the faulty PMIC can be disabled to prevent its incorrect operation from damaging downstream application devices.

In an embodiment, the main controller 110 may be an electronic control unit (ECU) or a host including the ECU. In another embodiment, the main controller 110 may be a micro control unit (MCU) or a host including the MCU. The present disclosure is not limited thereto. The main controller 110 may also be embedded in a separate PMIC, or may be embedded in the same PMIC as the power converter 120.

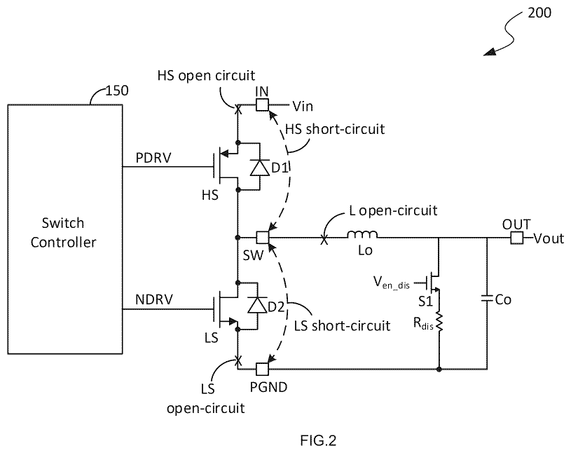

FIG. 2 illustrates an exemplary circuit diagram of a power stage 200. Referring to FIG. 2, the power stage 200 includes a first switch (also referred to as a high-side switch) HS, a second switch (also referred to as a low-side switch) LS, a power inductor L, and an output capacitor Co. In FIG. 2, the power stage 200 is implemented by using a circuit structure of a buck converter. Those skilled in the art should understand that, in another embodiment, the power stage 200 may also adopt other switching conversion circuit structures, such as a boost conversion circuit structure, a buck-boost conversion circuit structure, etc. The present disclosure is not limited thereto.

With continued reference to FIG. 2, the high-side switch HS includes a first terminal, a second terminal and a control terminal. In addition, the high-side switch HS further includes a body diode D1. The first terminal of the high-side switch HS is coupled to the input terminal IN of the power converter to receive the input voltage Vin. The low-side switch LS includes a first terminal, a second terminal and a control terminal. In addition, the low-side switch further includes a body diode D2. The first terminal of the low-side switch LS is coupled to the second terminal of the high-side HS to form a common connection node, the second terminal of the low-side switch LS is coupled to the reference ground terminal PGND. The switching terminal SW is coupled to one terminal of the power inductor L, and the other terminal of the power inductor L is coupled to one terminal of the output capacitor Co, and the other terminal of the output capacitor Co is coupled to the reference ground terminal PGND. A common terminal of the power inductor L and the output capacitor Co is connected to the output terminal OUT operative to supply the output voltage Vout to a load (not shown).

In an embodiment, each of the high-side switch HS and the low-side switch LS includes a controllable transistor. For example, FIG. 2 exemplarily shows a metal-oxide-semiconductor field-effect transistor (MOSFET). In the embodiment shown in FIG. 2, the high-side switch HS is a p-type metal-oxide-semiconductor, PMOS, the low-side switch LS is an n-type metal-oxide-semiconductor, NMOS. It should be understood that the present invention is not limited thereto. In an embodiment, the high-side switch HS and the low-side switch LS are both NMOSs. In this embodiment, the power converter may include a voltage bootstrap circuit (e.g., a bootstrap capacitor) to ensure that the high-side switch HS can be turned on accurately. The following description uses the example where the high-side switch HS is a PMOS and the low-side switch is an NMOS.

In addition, the power stage 200 may further include a forced discharge circuit, coupled between the output terminal OUT and the reference ground terminal PGND. The forced discharge circuit is configured to, for example, fast discharge the output capacitor Co connected to the output terminal OUT when the power converter 120 is in a standby mode or shutdown mode. In an embodiment, the forced discharge circuit comprises a switching component S1 and a discharge resistor Rdis connected in series. The switching element S1 may be, for example, a MOSFET having a first terminal, a second terminal and a control terminal, where the first terminal is coupled to the output terminal OUT, the second terminal is coupled to the reference ground terminal PGND, and the control terminal is configured to receive a discharge enable signal Ven_dis and is turned on under the control of the discharge enable signal Ven_dis.

As shown in FIG. 2, an abnormal connection event in the power stage 200 may include one of the following conditions: a condition where the switching terminal SW is shorted to the input terminal IN (which may also be referred to as HS short-circuit event), a condition where the switching terminal SW is shorted to the reference ground terminal PGND (which may also be referred to as LS short-circuit event), a condition where the power inductor L is disconnected from the switching terminal SW or a condition where the power inductor L is disconnected from the output terminal OUT (which may also be referred to as L open-circuit event), a condition where the high-side switch HS is disconnected from the input terminal IN or the high-side switch HS is disconnected from the switching terminal SW (which may also be referred to as HS open-circuit event), a condition where the low-side switch LS is disconnected from the reference ground terminal PGND or a condition where the low-side switch LS is disconnected from the switching terminal SW (which may also be referred to as LS open-circuit event), etc. Under these conditions, the power converter 120 will generate an abnormal connection warning signal (e.g., OS_FLAG) and send the abnormal connection warning signal to the main controller 110, and the main controller 110 then responds by disabling the power converter 120.

In the normal buck operation and in the condition where no abnormal connection event occurs, the high-side switch HS and the low-side switch LS are turned on and off under the control of the switch controller 150, so that the energy storage element (e.g., the power inductor L and the output capacitor Co) alternately stores and releases electric energy, thereby converting the input voltage Vin into the output voltage Vout. Specifically, the switch controller 150 may be controlled to provide a first driving signal HDRV and a second driving signal LDRV having a logic state opposite to that of the first driving signal HDRV respectively to the control terminals of the high-side switch HS and the low-side switch LS. For example, when the first driving signal HDRV is logic high and the second driving signal LDRV is logic low, the high-side switch HS is turned on, the low-side switch LS is turned off, and a current will flow from the input terminal IN through the high-side switch HS, the power inductor L and the output capacitor Co. Meanwhile, the current flowing through the power inductor L will flow into a load (not shown) through the output terminal OUT. When the first driving signal HDRV is logic low and the second driving signal LDRV is logic high, the high-side switch HS is turned off, the low-side switch LS is turned on, and a current will flow through the low-side switch LS, the power inductor L and the output capacitor Co. Meanwhile, the current flowing through the power inductor L flows into a load (not shown) through the output terminal OUT.

The power converter shown in FIG. 1 can determine whether an abnormal connection event occurs before the PMIC starts to operate through the abnormal connection event detection circuit built in the PMIC, and disable the faulty PMIC in advance to avoid further damage to the system caused by incorrect operation of the faulty chip.

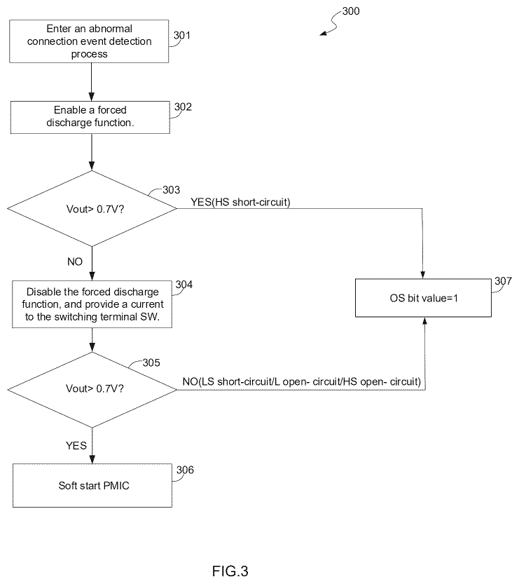

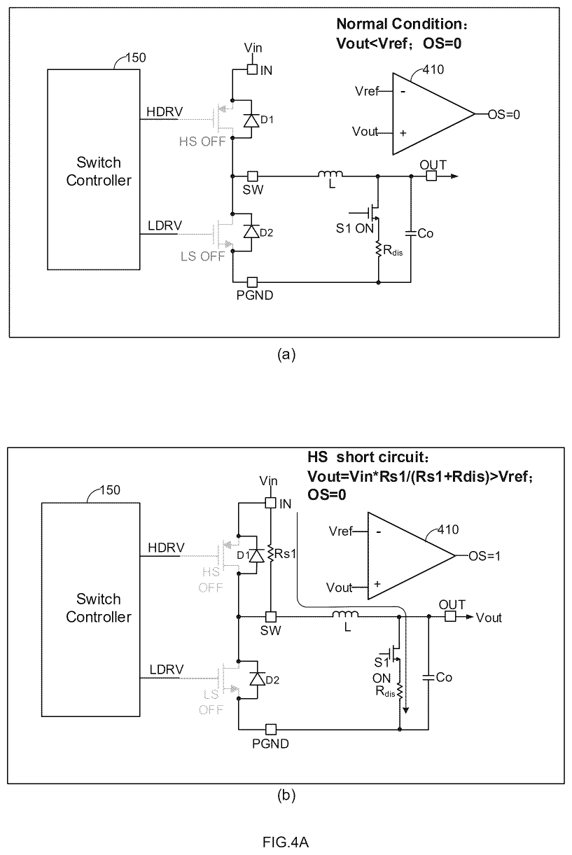

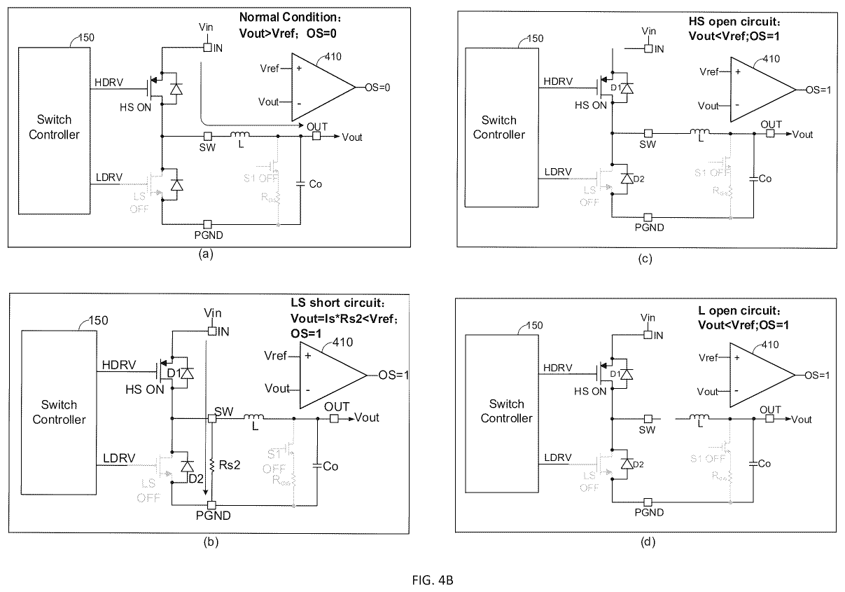

FIG. 3 shows a flowchart of a method 300 for detecting an abnormal connection event according to an embodiment of the present invention. The method 300 in FIG. 3 will be described in conjunction with FIG. 1, FIG. 2, and FIG. 4A-4B. For purposes of explanation, it will be assumed that the power management system has the form shown in FIG. 1.

Referring to FIG. 3, the method 300 includes the following steps 301-307.

Step 301: Enter an abnormal connection event detection process. For example, the abnormal connection event detection circuit 123 is enabled in response to receiving the input voltage Vin from the input terminal IN, thereby entering the abnormal connection event detection process. In an embodiment, the method 300 is performed before the soft start of the power converter 120, while the high-side switch HS and the low-side switch LS are all kept OFF.

Step 302: Enable a forced discharge function. In an embodiment, the control logic circuit 123-2 in the abnormal connection event detection circuit 123 may send a forced discharge enable signal Ven_dis to the control terminal of the MOSFET S1 to turn on the MOSFET S1, and to connect the output terminal OUT to the reference ground terminal PGND, so as to fast discharge the output capacitor Co, thereby reducing the output voltage Vout to zero volts (or close to zero volts).

Step 303: Compare the voltage Vout on the output terminal OUT with a reference voltage Vref, and determine whether the output voltage Vout is greater than the reference voltage Vref. In an embodiment, this step may be used to determine whether an HS short-circuit event occurs.

In an embodiment, the sensing circuit 123-1 in the abnormal event detection circuit 123 is configured to compare the output voltage Vout with the reference voltage Vref and output a sensing signal OS for indicating whether an abnormal connection event occurs. In an embodiment, the sensing circuit 123-1 may include a comparator 410, the comparator 410 has a first input terminal (e.g., a non-inverting input terminal) connected to the output terminal OUT, a second terminal (e.g., an inverting input terminal) connected to the reference voltage Vref and an output terminal operative to output the sensing signal OS. It should be understood that the sensing circuit 123-1 may include any circuit that may be used to compare the output voltage Vout with the reference voltage Vref.

FIG. 4A shows a schematic diagram of a circuit for determining whether an HS short-circuit event has occurred in method 300.

As shown in the sub-diagram (a) in FIG. 4A, in a case where no HS short-circuit event occurs, the output voltage Vout on the output terminal OUT is zero after forced discharging and less than the reference voltage Vref, that is, Vout<Vref, and at this time, the comparator 410 outputs OS=0, indicating that no aforementioned abnormal connection event (e.g., HS short-circuit event) occurs.

As shown in the sub-diagram (b) in FIG. 4A, if an HS short-circuit event occurs (for example, at this time, the path between the input terminal IN and the switching terminal SW may be equivalent to a resistor Rs1 with a small resistance value), there will be a current flowing from the input terminal IN to the reference ground terminal PGND through the resistor Rs1, the switching terminal SW, the inductor L, the switch S1 and the discharge resistor Rdis. At this time, the output voltage Vout=Vin*Rdis/(Rs1+Rdis). By setting the value of the reference voltage Vref to be greater than 0V and less than Vin*Rdis/(Rs1+Rdis), it can be determined by the comparator 410 whether an HS short-circuit event occurs. In an example, when an abnormal connection event occurs, for example, Vin=3.3 V, Rs1=1 mΩ, and Rdis=2Ω, thereby Vout≈3.3 V. In this example, the reference voltage Vref may be set to 0.7 V. Since the output voltage Vout is greater than 0.7 V, the comparator 410 outputs OS=1 at this time, indicating that an HS short-circuit event occurs.

Referring back to FIG. 3, when it is determined that the output voltage Vout is greater than the reference voltage Vref (303=YES), indicating that an HS short-circuit occurs, the method proceeds to step 307. Otherwise (303=NO), the method proceeds to step 304 to continue to determine whether other type of abnormal connection event occurs.
Step 304: Disable the forced discharge function, and provide a current from the input terminal IN to the switching terminal SW. For example, the control logic circuit 123-2 in the abnormal connection event detection circuit 123 may enable the high-side switch HS to work in a linear amplification region (or the variable resistance region) by controlling the voltage provided to the control terminal of the high-side switch HS, thereby controlling the magnitude of the current flowing from the input terminal IN to the switching terminal SW.
Step 305: Compare the voltage Vout with a reference voltage Vref, and determine whether the output voltage Vout is greater than the reference voltage Vref. In an embodiment, this step may be used to determine whether an LS short-circuit event, an L open-circuit event or an HS open-circuit occurs.

FIG. 4B shows a schematic diagram of a circuit for determining whether an LS short-circuit event, an L open-circuit event, or an HS open-circuit event has occurred in method 300.

As shown in the sub-diagram (a) in FIG. 4B, in a case where no abnormal connection event occurs, the input voltage Vin magnetizes the inductor through the high-side switch HS and charges the capacitor Co, and after a certain time, the output voltage Vout becomes greater than the reference voltage Vref, and the comparator 410 outputs OS=0, indicating that no LS short-circuit event, L open-circuit event or HS open-circuit event occurs.

As shown in the sub-diagram (b) in FIG. 4B, if an LS short-circuit event occurs (for example, in this case, a path between the switching terminal SW and the reference ground terminal PGND may be equivalent to a resistor Rs2, and a resistance value of the resistor Rs2 is usually small), there is a current flows from the input terminal IN to the reference ground terminal PGND through the high-side switch HS, the switching terminal SW, and the resistor Rs2. The output voltage Vout is close to 0V, less than the reference voltage Vref, and the comparator 410 outputs OS=1, indicating that an abnormal connection event occurs, for example, an LS short-circuit event occurs.

As shown in the sub-diagram (c) in FIG. 4B, if an HS open-circuit event occurs, since the switching terminal SW is disconnected from the input voltage Vin, the output voltage Vout will be maintained at 0V, which is less than the reference voltage Vref, and the comparator 410 outputs OS =1, indicating that an abnormal connection event occurs, such as an HS open-circuit event occurs.

As shown in the sub-diagram (d) in FIG. 4B, if an L open-circuit event occurs, for example, the power inductor L is disconnected from the switching terminal SW, the output voltage Vout on the output terminal OUT will also be maintained at 0V, which is less than the reference voltage Vref, the comparator 410 outputs OS=1, indicating that an abnormal connection event occurs, for example, an L open-circuit event occurs.

After step 305, the method 300 may further include a step (not shown) for detecting an LS open-circuit event (e.g., the switching terminal SW is disconnected from the reference ground terminal PGND). In this step, the low-side switch LS is turned on, and a current is provided from the input terminal VIN to the switching terminal SW, and if no current is detected to flow through the low-side switch LS, then output sensing signal OS=1, indicating that an abnormal connection event occurs, e.g., an LS open-circuit event occurs. For example, the abnormal connection event detection circuit may further include a current sensing circuit for detecting whether a current flows through the low-side switch LS.
Step 306: Normal start (e.g., soft start) PMIC.

Step 307: Set a bit value of the abnormal connection event register to a first value (e.g., 1). For example, the control logic circuit 123-2 in the abnormal connection event detection circuit 123 may set the bit value of the abnormal connection event register to the first value based on the signal OS=1 output by the comparator 410. Further, the communication module 124 may generate an abnormal connection event warning signal OS_FLAG in response to the bit value in the abnormal connection event register being set to the first value, and send the abnormal connection event warning signal OS_FLAG to the external main controller 110 through the communication terminal UART. The master controller 110 will not enable the faulty PMIC.

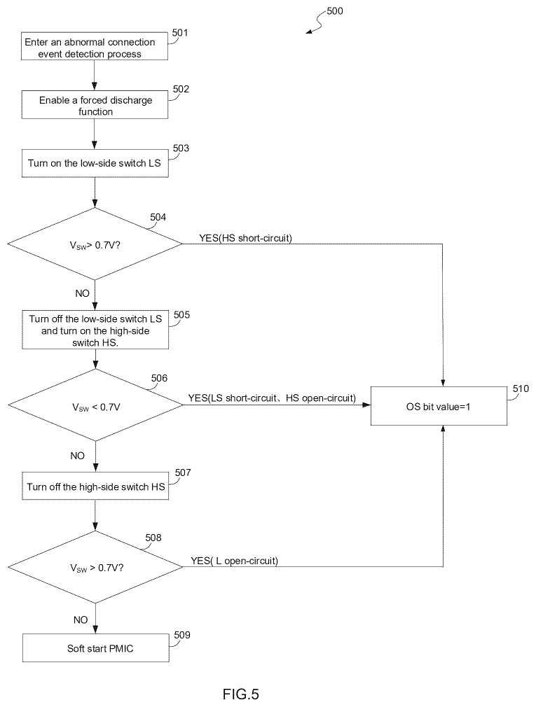

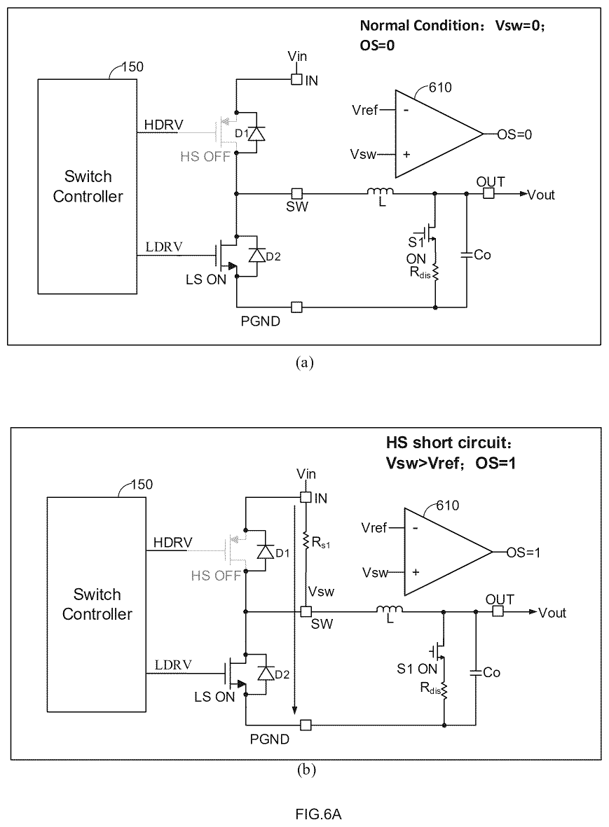

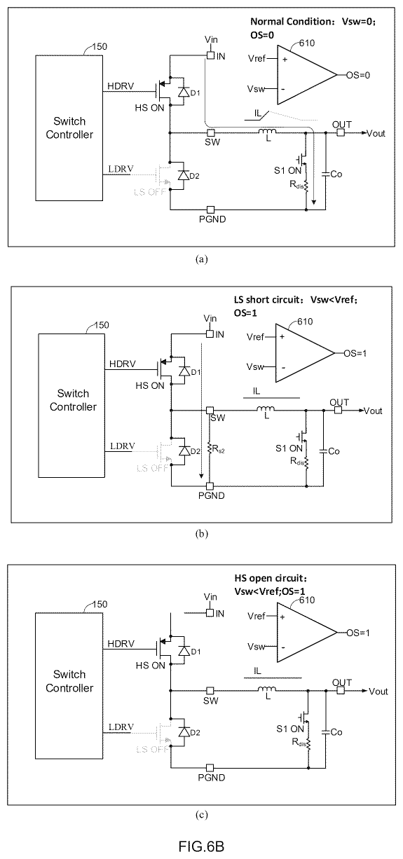

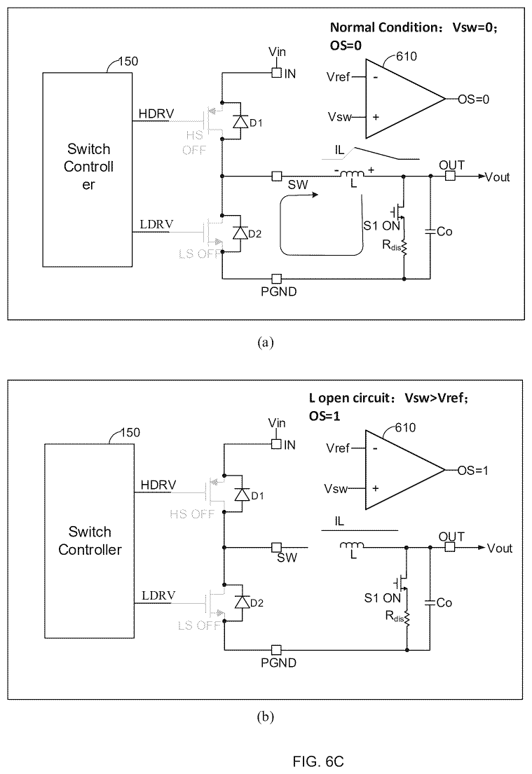

FIG. 5 shows a flowchart of a method 500 for detecting an abnormal connection event according to an embodiment of the present invention. The method 500 in FIG. 5 will be described in conjunction with FIG. 1, FIG. 2, and FIG. 6A-6C. For the purpose of explanation, it will be assumed that the power management system has the form shown in FIG. 1.

Referring to FIG. 5, the method 500 includes the following steps 501-510.
Step 501: Enter an abnormal connection event detection process. For example, the abnormal connection event detection circuit 123 is enabled in response to receiving the input voltage Vin from the input terminal IN, thereby entering the abnormal connection event detection process. In an embodiment, the method 500 is performed before the soft start of the power converter 120, while the high-side switch HS, the low-side switch LS are all kept OFF.
Step 502: Enable a forced discharge function. In an embodiment, the control logic circuit 123-2 in the abnormal event detection circuit 123 may send a forced discharge enable signal Ven_dis to the control terminals of the MOSFET S1, so as to fast discharge the output capacitor Co, thereby reducing the output voltage Vout to zero volts (or close to zero volts). In a case where no L open-circuit event occurs, the voltage Vsw on the switching terminal SW decreases to zero (or close to zero volts).
Step 503: Turn on the low-side switch LS. In an embodiment, the control logic circuit 123-2 in the abnormal connection event detection circuit 123 may send a high level signal to the control terminal of the low side switch LS for a predetermined time (e.g., 200 ns) to turn on the low side switch LS for a predetermined time.
Step 504: Compare the switching voltage Vsw on the switching terminal SW with a reference voltage Vref, and determine whether the switching voltage Vsw is greater than the reference voltage Vref. In an embodiment, this step may be used to determine whether an HS short-circuit event occurs.

In an embodiment, the sensing circuit 123-1 in the abnormal event detection circuit 123 is configured to compare the switching voltage Vsw with the reference voltage Vref and output a sensing signal OS for indicating whether an abnormal connection event occurs. In an embodiment, the sensing circuit 123-1 may include a comparator 610 having a first input (e.g., a non-inverting input), a second input (e.g., an inverting input), and an output. The comparator 610 has a first input terminal connected to the switching terminal SW, a second input terminal connected to the reference voltage Vref, and an output terminal for outputting the sensing signal OS. It should be understood that the sensing circuit 123-1 may include any circuit that may be used to compare the output voltage Vout with the reference voltage Vref.

FIG. 6A shows a schematic diagram of a circuit for determining whether an HS short-circuit event has occurred in method 500.

As shown in the sub-diagram (a) in FIG. 6A, in a case where no HS short-circuit event occurs, since the forced discharge function remains turned on, the switching voltage Vsw on the switching terminal SW is equal to 0 and less than the reference voltage Vref, and at this time, the comparator 610 outputs OS=0, indicating that no abnormal connection event occurs.

As shown in the sub-diagram (b) of FIG. 6A, if an HS short-circuit event occurs (for example, at this time, the path between the input terminal IN and the switching terminal may be equivalent to a resistor Rs1 with a small resistance value), there will be a current flowing from the input terminal IN to the reference ground terminal PGND through the resistor Rs1, the switching terminal SW and the low-side switch LS. At this time, the voltage Vsw is close to the input voltage and greater than the reference voltage Vref (e.g., 0.7 V), and the comparator 610 outputs OS=1, indicating that an HS short-circuit event occurs.

Referring back to FIG. 5, when it is determined in step 504 that the switching voltage Vsw is greater than the reference voltage Vref (504=YES), indicating that an HS short-circuit event occurs, the method proceeds to step 510. Otherwise (504=NO), and the method proceeds to step 505 to continue to determine whether other abnormal connection events occur.
Step 505: turn off the low-side switch LS and turn on the high-side switch HS. In an embodiment, the control logic circuit 123-2 in the abnormal connection event detection circuit 123 may send a low level signal to the control terminal of the high-side switch HS for a predetermined time (e.g., 200 ns) to turn on the high-side switch HS for a predetermined time.
Step 506: Compare the switching voltage Vsw on the switching terminal SW with the reference voltage Vref, and determine whether the switching voltage Vsw is greater than the reference voltage Vref. In an embodiment, this step may be used to determine whether an LS short-circuit event occurs.

In an embodiment, the sensing circuit 123-1 in the abnormal connection event detection circuit 123 is configured to compare the switching voltage Vsw with the reference voltage Vref and output a sensing signal OS for indicating whether an LS short-circuit event occurs. In an embodiment, the sensing circuit 123-1 may include a comparator 610 having a first input terminal (e.g., an inverting input terminal) connected to the switching terminal SW, a second input terminal (e.g., a non-inverting input terminal) connected to the reference voltage Vref, and an output terminal for outputting the sensing signal OS. It should be understood that the sensing circuit 123-1 may include any circuit that may be used to compare the output voltage Vout with the reference voltage Vref.

FIG. 6B shows a schematic diagram of a circuit for determining whether an LS short-circuit event or an HS open-circuit event has occurred in method 500.

As shown in the sub-diagram (a) of FIG. 6B, in a case where no aforementioned abnormal connection event occurs, a current flows from the input terminal IN to the reference ground terminal PGND through the high-side switch HS, the switching terminal SW, the power inductor L, the switching element S1 and the discharge resistor Rdis, and the current flowing through the power inductor L ramps upward, so that the power inductor L stores energy in this process. At this time, the switching voltage Vsw on the switching terminal SW is close to the induced voltage on the power inductor L. By setting the value of the reference voltage Vref to a sensing voltage greater than 0V and less than the induced voltage on the power inductor L, it can be determined by the comparator 610 whether an HS short-circuit event occurs. For example, in this example, the reference voltage Vref may also be set to 0.7 V. Since the switching voltage Vsw is greater than the reference voltage at this time, the comparator 610 outputs OS=0 at this time, indicating that no LS short-circuit event occurs.

As shown in the sub-diagram (b) in FIG. 6B, if an LS short-circuit event occurs (for example, at this time, the path between the switching terminal and the reference ground terminal PGND may be equivalent to a resistor Rs2 with usually a small resistance value), the current will flow from the input terminal IN to the reference ground terminal PGND through the high-side switch HS, the switching terminal SW and the resistor Rs2. At this time, the switching voltage Vsw is close to 0V and less than the reference voltage Vref (e.g., 0.7 V), and the comparator 610 outputs OS=1, indicating that an abnormal connection event occurs, such as an LS short-circuit event occurs.

As shown in diagram (c) in FIG. 6B, if an HS open-circuit event occurs, since the switching terminal SW is disconnected from the input voltage Vin, the voltage Vsw will be maintained at 0V, which is less than the reference voltage Vref, and the comparator 610 outputs OS=1, indicating that an abnormal connection event occurs, such as an HS open-circuit event occurs.

Referring back to FIG. 5, when it is determined in step 506 that the voltage Vsw is less than the reference voltage Vref (506=YES), indicating that the aforementioned abnormal connection event occurs, and the method proceeds to step 510. Otherwise (506=NO), and the method proceeds to step 507 to continue to determine whether other abnormal connection event occur.
Step 507: Further turn off the high-side switch HS. In an embodiment, the control logic circuit 123-2 in the abnormal connection event detection circuit 123 sends a low level signal to turn off the high-side switch HS after a predetermined time (e.g., 200 ns).
Step 508: Compare the switching voltage Vsw on the switching terminal with the reference voltage Vref, and determine whether the switching voltage Vsw is greater than the reference voltage Vref. In an embodiment, this step may be used to determine whether an L open-circuit event has occurred.

FIG. 6C shows a schematic diagram of a circuit for determining whether an L open-circuit event has occurred.

As shown in the sub-diagram (a) of FIG. 6C, in a case where no L open-circuit event occurs, after HS is turned off, the power inductor L starts to discharge power. The power inductor current flows through the switching element S1, the discharge resistor Rdis, the reference ground terminal PGND, the body diode D2 of the low-side switch LS and the switching terminal SW. The voltage on the switching terminal SW becomes a negative voltage which is less than the reference voltage Vref, the comparator 610 outputs OS=0, indicating that no L open-circuit event occurs.

As shown in the sub-diagram (b) of FIG. 6C, if an L open-circuit event occurs (for example, at this time, the power inductor L is disconnected from the switching terminal SW), after the high-side switch HS is turned off, since there is no leakage path, the switching terminal SW will maintain a high voltage which is greater than the reference voltage Vref, and the comparator 610 outputs OS=1, indicating that an abnormal connection event occurs, for example, an L open-circuit event occurs.

After step 508, the method 500 may further include a step (not shown) for detecting an LS open-circuit event (e.g., disconnection of the switching terminal SW from the reference ground terminal PGND). In this step, the low-side switch LS is turned on, and a current is provided from the input terminal VIN to the switching terminal SW, and if no current is detected to flow through the low-side switch LS, the sensing signal OS=1 is output, indicating that an abnormal connection event occurs, such as an LS open-circuit event occurs. For example, the abnormal connection event detection circuit may further include a current sensing circuit for detecting whether a current flows through the low-side switch LS.

Referring back to FIG. 5, when it is determined in step 508 that the switching voltage Vsw is greater than the reference voltage Vref (508=YES), indicating that an L open-circuit event occurs, the method proceeds to step 510. Otherwise (508=NO), the method proceeds to step 509.
Step 509: Normal start (e.g., soft start) PMIC.
Step 510: Set the bit value of the abnormal event register to a first value (for example, 1). For example, the control logic circuit 123-2 in the abnormal event detection circuit 123 may set the bit value of the abnormal event register to the first value based on the signal OS=1 output by the comparator 610. Further, the communication module 124 may generate an abnormal connection warning signal OS_FLAG in response to the bit value being set to the first value, and send the abnormal connection warning signal OS_FLAG to the external main controller 110 through the communication terminal UART. The master controller 110 will not enable the faulty PMIC.

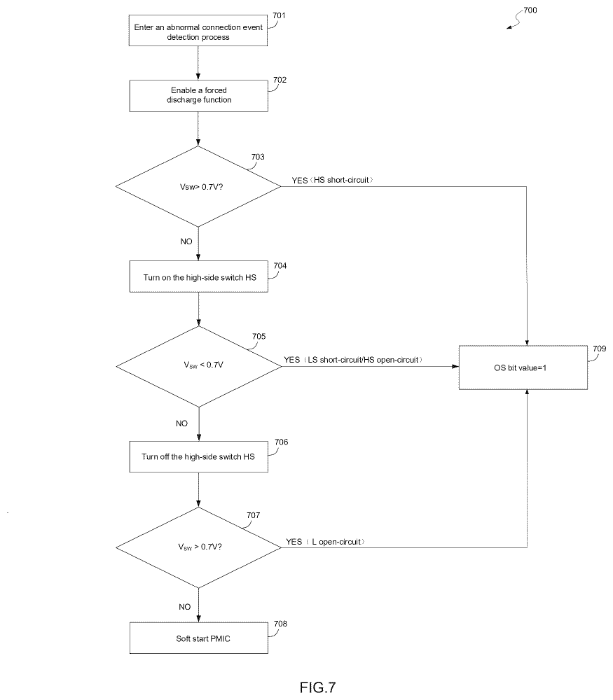

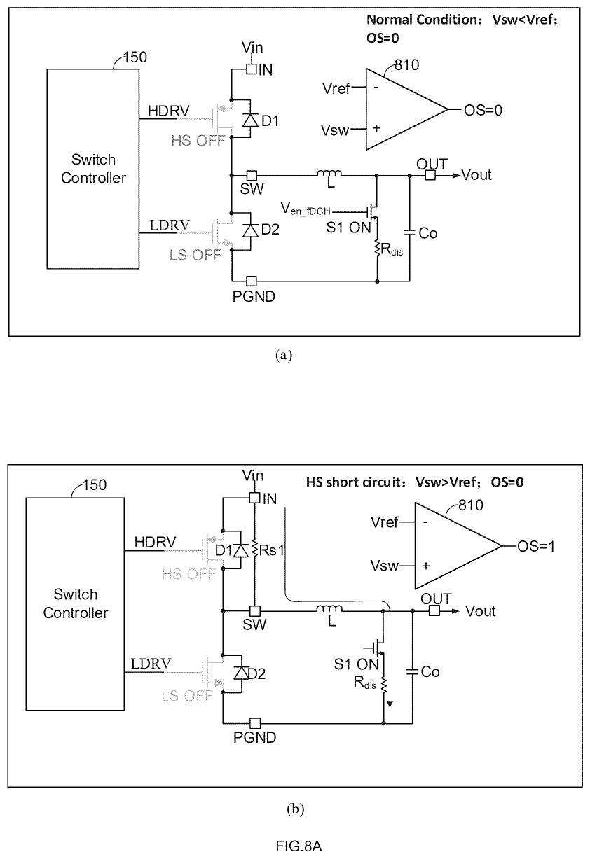

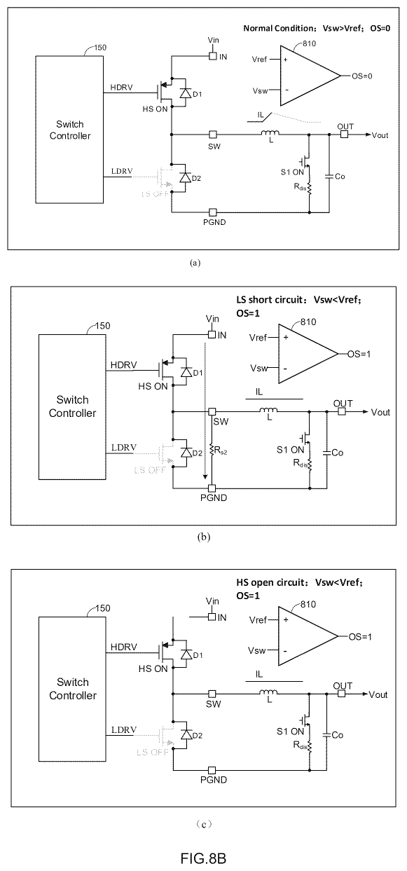

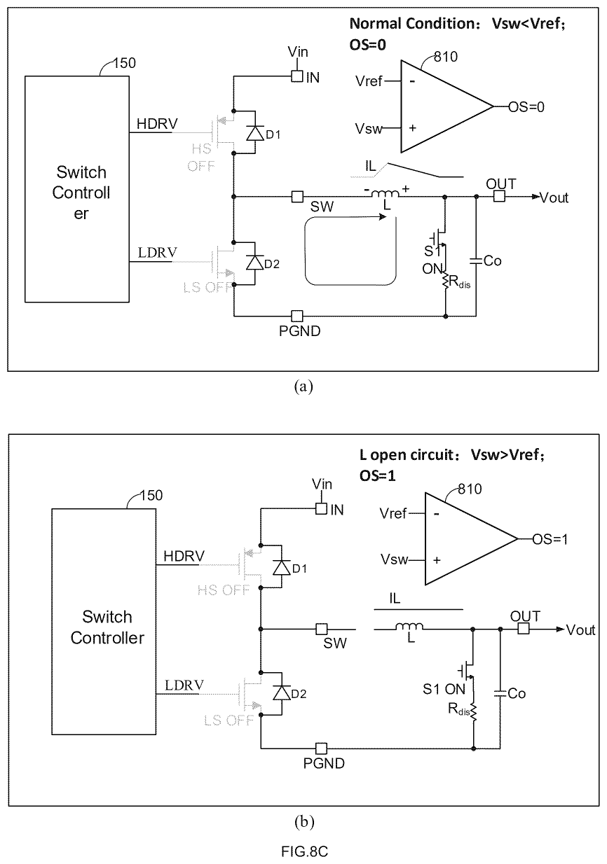

FIG. 7 shows a flowchart illustrating a method 700 for detecting an abnormal connection event according to an embodiment of the present invention. The method 700 in FIG. 7 will be described in conjunction with FIG. 1, FIG. 2, and FIG. 8A-8C. For purposes of explanation, it will be assumed that the power management system has the form shown in FIG. 1.

Referring to FIG. 7, the method 700 includes the following steps 701-709.
Step 701: Enter an abnormal connection event detection process. For example, the abnormal connection event detection circuit 123 is enabled in response to receiving the input voltage Vin from the input terminal IN, thereby entering the abnormal connection event detection process. In an embodiment, the method 700 is performed before the soft-start of the power converter 120, while the high-side switch HS and the low-side switch LS are all kept OFF.
Step 702: Enable a forced discharge function. In an embodiment, the control logic circuit 123-2 in the abnormal connection event detection circuit 123 may send a forced discharge enable signal Ven_dis to the control terminal of the MOSFET S1 to turn on the MOSFET S1 and connect the output terminal OUT to the reference ground terminal PGND, so as to fast discharge the output capacitor Co, thereby reducing the voltage Vsw to zero volts (or close to zero volts). In a case where no L open-circuit occurs, the voltage Vsw on the switching terminal SW also drops to zero volts (or close to zero volts).
Step 703: Compare the voltage Vsw on the switching terminal SW with the reference voltage Vref, and determine whether the voltage Vsw is greater than the reference voltage Vref. In an embodiment, this step may be used to determine whether an HS short-circuit event occurs.

In an embodiment, the sensing circuit 123-1 in the abnormal connection event detection circuit 123 is configured to compare the voltage Vsw with the reference voltage Vref and output a sensing signal OS for indicating whether an abnormal connection event occurs. In an embodiment, the sensing circuit 123-1 may include a comparator 810 having a first input (e.g., a non-inverting input), a second input (e.g., an inverting input), and an output. The comparator 810 has a first input terminal connected to the switching terminal SW, a second input terminal connected to the reference voltage Vref, and an output terminal for outputting the sensing signal OS. It should be understood that sense circuit 123-1 may include any circuit that may be used to compare voltage Vsw to reference voltage Vref.

FIG. 8A shows a schematic diagram of a circuit for determining whether an HS short-circuit event has occurred in method 700.

As shown in the sub-diagram (a) in FIG. 8A, in a case where no HS short-circuit event occurs, after forced discharge, the switching voltage Vsw on the switching terminal SW is equal to 0 and less than the reference voltage Vref (e.g., 0.7 V), and at this time, the comparator 810 outputs OS=0, indicating that no abnormal connection event occurs.

As shown in the sub-diagram (b) in FIG. 8A, if an HS short-circuit event occurs (for example, at this time, the path between the input terminal IN and the switching terminal may be equivalent to a resistor Rs1 with a small resistance value), there will be a current flowing from the input terminal IN to the reference ground terminal PGND through the resistor Rs1, the inductor L and the discharge resistor Rdis. At this time, the switching voltage Vsw=Vin*Rdis/(Rs1+Rdis). By setting the value of the reference voltage Vref to be greater than 0V and less than Vin*Rdis/(Rs1+Rdis), it can be determined by the comparator 810 whether an HS short-circuit event occurs. In an example, when an abnormal connection event occurs, for example, Vin=3.3 V, Rs1=1 mΩ, and Rdis=2Ω, thereby Vout≈3.3 V. Based on this, the reference voltage Vref may be set to 0.7 V. Since the switching voltage Vsw is greater than 0.7 V, the comparator 810 outputs OS=1 at this time, indicating that an HS short-circuit event occurs.

Referring back to FIG. 7, when it is determined in step 703 that the switching voltage Vsw is greater than the reference voltage Vref (703=YES), it is determined that an HS short-circuit event occurs, and the method proceeds to step 709. Otherwise (703=NO), the method proceeds to step 704 to continue to determine whether other types of abnormal connection events occur, such as an LS short-circuit event or an HS open-circuit event.
Step 704: Turn on the high-side switch HS. In an embodiment, the control logic circuit 123-2 in the abnormal connection event detection circuit 123 may send a low level signal to the control terminal of the high-side switch HS for a predetermined time (e.g., 200 ns) to turn on the high-side switch HS for a predetermined time.
Step 705: Compare the switching voltage Vsw on the switching terminal SW with the reference voltage Vref, and determine whether Vsw is less than the reference voltage Vref, thereby determining whether an LS short-circuit event or an HS open-circuit event occurs.

In an embodiment, the sensing circuit 123-1 in the abnormal connection event detection circuit 123 is configured to compare the switching voltage Vsw with the reference voltage Vref and output a sensing signal OS for indicating whether an LS short-circuit event or an HS open-circuit event occurs. In an embodiment, the sensing circuit 123-1 may include a comparator 810 having a first input terminal (e.g., an inverting input terminal) connected to the switching terminal, a second input terminal (e.g., a non-inverting input terminal) connected to the reference voltage Vref, and an output terminal for outputting the sensing signal OS. It should be understood that sense circuit 123-1 may include any circuit that may be used to compare voltage Vsw to reference voltage Vref.

FIG. 8B shows a schematic diagram of a circuit for determining whether an LS short-circuit event or an HS open-circuit event has occurred in method 700.

As shown in the sub-diagram (a) of FIG. 8B, in an case where the aforementioned abnormal connection event does not occur, the current flows from the input terminal IN to the reference ground terminal PGND through the high-side switch HS, the switching terminal SW, the power inductor L, the switching element S1 and the discharge resistor Rdis, and the current flowing through the power inductor L ramps upward to store energy in the power inductor L. At this time, the switching voltage on the switching terminal SW is greater than the reference voltage Vref, and the comparator 810 outputs OS=0, indicating that no LS short-circuit event occur.

As shown in the sub-diagram (b) in FIG. 8B, if an LS short-circuit event occurs (for example, at this time, the path between the switching terminal and the reference ground terminal PGND may be equivalent to a resistance Rs2 with usually a small resistance value), the current will flow from the input terminal IN to the reference ground terminal PGND through the high-side switch HS, the switching terminals SW and the resistor Rs2. At this time, the switching voltage Vsw on the switching terminal is close to zero volts and less than the reference voltage Vref, and the comparator 810 outputs OS=1, indicating that an abnormal connection event occurs, for example, an LS short-circuit event occurs.

As shown in diagram (c) in FIG. 8B, if an HS open-circuit event occurs, since the switching terminal SW is disconnected from the input voltage Vin, the voltage Vsw will be maintained at 0V, which is less than the reference voltage Vref, and the comparator 610 outputs OS=1, indicating that an abnormal connection event occurs, such as an HS open-circuit event occurs.

Referring back to FIG. 7, when it is determined in step 705 that the voltage Vsw is less than the reference voltage Vref (705=YES), indicating that the aforementioned abnormal connection event occurs, and the method proceeds to step 709. Otherwise (705=NO), and the method proceeds to step 706, to continue to determine whether other abnormal connection event occurs, for example, an L open-circuit event occurs.
Step 706: Further turn off the high-side switch HS. In an embodiment, the control logic circuit 123-2 in the abnormal connection event detection circuit 123 may send a low level signal to the control terminal of the high-side switch HS after the aforementioned predetermined time (e.g., 200 ns) to turn off the high-side switch HS.
Step 707: Compare the switching voltage Vsw on the switching terminal SW with the reference voltage Vref, and determine whether the switching voltage Vsw is greater than the reference voltage Vref. In an embodiment, this step may be used to determine whether an L open-circuit event has occurred.

FIG. 8C shows a schematic diagram of a circuit for determining whether an L open-circuit event has occurred in method 700.

As shown in the sub-diagram (a) of FIG. 8C, in a case that no L open-circuit event occurs, after the high-side switch HS is turned off, the power inductor L starts to release power. The power inductor current flows through the switching element S1, the discharge resistor Rdis, the reference ground terminal PGND, the body diode D2 of the low-side switch LS, and the switching terminal SW. The voltage on the switching terminal SW becomes a negative voltage which is less than the reference voltage Vref, the comparator 810 outputs OS=0, indicating that no L open-circuit event has occurred.

As shown in FIG. 8C (b), if an L open-circuit event occurs, after the high-side switch HS is turned off, since there is no leakage path, the switching terminal SW will maintain a high voltage which is greater than the reference voltage Vref, and the comparator 810 outputs OS=1, indicating that an abnormal connection event occurs, such as an L open-circuit event occurs.

After step 707, the method 700 may further include a step (not shown) for detecting an LS open-circuit event (e.g., disconnection of the switching terminal SW from the reference ground terminal PGND). In this step, the low-side switch LS is turned on, and a current is provided from the input terminal VIN to the switching terminal SW, and if no current is detected to flow through the low-side switch LS, the sensing signal OS=1 is output, indicating that an abnormal connection event occurs, such as an LS open-circuit event occurs. For example, the abnormal connection event detection circuit may further include a current sensing circuit for detecting whether a current flows through the low-side switch LS.

Referring back to FIG. 7, when it is determined that the voltage Vsw is greater than the reference voltage Vref (707=YES), indicating that an L open-circuit event occurs, the method proceeds to step 708. Otherwise (707=NO), the method proceeds to step 709.
Step 708: Normal start (e.g., soft start) PMIC.
Step 709: Set the bit value of the exception event register to a first value (for example, 1). For example, the control logic circuit 123-2 in the abnormal event detection circuit 123 may set the bit value of the abnormal event register to the first value based on the signal OS=1 output by the comparator 810. Further, the communication module 124 may generate the abnormal connection warning signal OS_FLAG in response to the bit value in the abnormal connection event register being set to the first value, and send the abnormal connection warning signal OS_FLAG to the external main controller 110 through the communication terminal UART. The master controller 110 will not enable the faulty PMIC.

Although the flowcharts of FIG. 3, FIG. 5, and FIG. 7 show sequential steps. It will be apparent to those skilled in the art that these actions may be performed in any appropriate order, and may perform only some of them, which is not limited by the present disclosure.

Thus, the present application discloses a fault self-detection circuit and corresponding method for protecting PMIC circuit components from short-circuit events or open-circuit events or other problems. Whether an abnormal connection event occurs can be detected in time before the PMIC is formally started, and the faulty chip can be disabled to avoid further damage caused by incorrect operation damage of the faulty chip, thereby improving the reliability of the PMIC.

It will be appreciated by those skilled in the art that the present disclosure is not limited to that has been particularly shown and described hereinabove. Rather, the scope of the present disclosure is defined by the claims and includes both combinations and sub-combinations of the various features described hereinabove, as well as variations and modifications thereof which would occur to those skilled in the art upon reading the foregoing description and which are not in the prior art.

1. An integrated circuit for a power conversion circuit, comprising:
an input terminal, configured to receive an input voltage,
an output terminal, configured to provide an output voltage,
a reference ground terminal, configured to be coupled to a reference ground voltage,
a switching terminal, configured to be coupled to a common connection node of a high-side switch and a low-side switch, wherein the high-side switch and the low-side switch are coupled in series between the input terminal and the reference ground terminal, and
an abnormal connection event detection circuit, configured to detect an abnormal connection event in the power conversion circuit before the power conversion circuit starts, and further generate an abnormal connection warning signal for indicating the abnormal connection event based on detecting that the abnormal connection event occurs.

2. The integrated circuit of claim 1, further comprising:
an enable terminal, configured to receive an enable signal, wherein “before the power conversion circuit starts” means that the integrated circuit did not receive the enable signal through the enable terminal.

3. The integrated circuit of claim 2, wherein the integrated circuit receives the enable signal through the enable terminal when no abnormal connection event occurs in the power conversion circuit.

4. The integrated circuit of claim 1, wherein the abnormal connection event comprises one or more of the following events: the switching terminal being shorted to the input terminal, the switching terminal being shorted to the reference ground terminal, the high-side switch being disconnected from the input terminal, the high-side switch being disconnected from the switching terminal, the low-side switch being disconnected from the reference ground terminal, and the low-side switch being disconnected from the switching terminal.

5. The integrated circuit of claim 4, wherein the switching terminal is configured to be coupled to one end of a power inductor, the output terminal is configured to be coupled to the other end of the power inductor, the high-side switch and the low-side switch are configured to be turned on or off under the control of a control signal, thus to increase or decrease an inductor current flowing through the power inductor, thereby converting the input voltage into the output voltage, and wherein the abnormal connection event further comprises: the switching terminal being disconnected from the power inductor, the power inductor being disconnected from the output terminal.

6. The integrated circuit of claim 1, further comprising a communication terminal, configured to provide the abnormal connection warning signal to a master controller.

7. The integrated circuit of claim 1, wherein the abnormal connection event detection circuit comprises:
a sensing circuit, configured to compare a switching voltage on the switching terminal or the output voltage on the output terminal with a reference voltage, and further generate a sensing signal based on a comparison result; and
a control logic circuit, configured to generate the abnormal connection warning signal in response to the sensing signal having a set logic state.

8. The integrated circuit of claim 7, further comprising:
a forced discharge circuit, coupled to the output terminal, configured to discharge the output terminal.

9. The integrated circuit of claim 8, the forced discharge circuit comprising a switching component and a discharge resistor coupled in series between the output terminal and the reference ground terminal, wherein the switching element is configured to be turned on in response to a discharge enable signal from the control logic circuit, thereby connecting the output terminal to the reference ground terminal.

10. The integrated circuit of claim 7, wherein the control logic circuit further comprises a register dedicated for recording the abnormal connection event, and wherein the control logic circuit is configured to set a bit value of the register to a first value in response to the sense signal having the set logic state.

11. The integrated circuit of claim 8, wherein the abnormal event detection circuit is configured to be enabled in response to the input voltage, thereby entering an abnormal connection event detection procedure.

12. The integrated circuit of claim 11, wherein, in the abnormal connection event detection procedure, the control logic circuit is configured to perform one or more of the following steps:
enabling the forced discharge circuit, so as to connect the output terminal to the reference ground terminal,
controlling the sensing circuit to compare an output voltage on the output terminal with the reference voltage to determine whether the output voltage is greater than the reference voltage, wherein if the output voltage is greater than the reference voltage, the sensing circuit outputs the sensing signal having the set logic state; if the output voltage is less than the reference voltage, the sensing circuit outputs the sensing signal having a reset logic state;
if the output voltage is less than the reference voltage, disabling the forced discharge circuit to disconnect the output terminal from the reference ground terminal, and controlling providing a current from the input terminal to the switching terminal;
controlling the sensing circuit to compare the output voltage with the reference voltage to determine whether the output voltage is greater than the reference voltage, wherein if the output voltage is greater than the reference voltage, the sensing circuit outputs the sensing signal having the reset logic state, and if the output voltage is less than the reference voltage, the sensing circuit outputs the sensing signal having the set logic state.

13. The integrated circuit of claim 12, further comprising a current sensing circuit, wherein the control logic circuit is further configured to:
provide a current from the input terminal to the switching terminal and turn on the low-side switch, and
control the current sensing circuit to detect whether there is a current flows through the low-side switch,
wherein if it is detected that there is a current flows through the low-side switch, the current sensing circuit outputs the sensing signal having the reset logic, and if no current is detected to flow through the low-side switch, the current sensing circuit outputs the sensing signal having the set logic state.

14. The integrated circuit of claim 11, wherein, in the abnormal connection event detection procedure, the control logic circuit is configured to perform one or more of the following steps:
enabling the forced discharge circuit, so as to connect the output terminal to the reference ground terminal;
turning on the low-side switch and controlling the sensing circuit to compare the switching voltage on the switching terminal with the reference voltage to determine whether the switching voltage is greater than the reference voltage, wherein if the switching voltage is greater than the reference voltage, the sensing circuit outputs the sensing signal having the set logic state; if the switching voltage is less than the reference voltage, the sensing circuit outputs a sensing signal having a reset logic state;
if the switching voltage is less than the reference voltage, turning off the low-side switch and turning on the high-side switch, and controlling the sensing circuit to compare the switching voltage on the switching terminal with the reference voltage to determine whether the switching voltage is less than the reference voltage, wherein if the switching voltage is greater than the reference voltage, the sensing circuit outputs the sensing signal having the reset logic state; if the switching voltage is less than the reference voltage, the sensing circuit outputs the sensing signal having the set logic state;
if the switching voltage is greater than the reference voltage, turning off the high-side switch and the low-side switch, and controlling the sensing circuit to compare the switching voltage on the switching terminal with the reference voltage to determine whether the switching voltage is greater than the reference voltage, wherein if the switching voltage is greater than the reference voltage, the sensing circuit outputs the sensing signal having the set logic state; and if the switching voltage is less than the reference voltage, the sensing circuit outputs the sensing signal having the reset logic state.

15. The integrated circuit of claim 14, further comprising a current sensing circuit, wherein the control logic circuit is further configured to:
provide a current from the input terminal to the switching terminal and turn on the low-side switch, and
control the current sensing circuit to detect whether there is a current flow through the low-side switch,
wherein if it is detected that there is a current flow through the low-side switch, the current sensing circuit outputs the sensing signal having the reset logic state, and if no current is detected to flow through the low-side switch, the current sensing circuit outputs the sensing signal having the set logic state.

16. The integrated circuit of claim 11, wherein, in the abnormal connection event detection procedure, the control logic circuit is configured to perform one or more of the following steps:
enabling the forced discharge circuit, so as to connect the output terminal to the reference ground terminal;
controlling the sensing circuit to compare the switching voltage on the switching terminal with the reference voltage to determine whether the switching voltage is greater than the reference voltage, wherein if the switching voltage is greater than the reference voltage, the sensing circuit outputs the sensing signal having the set logic state; if the switching voltage is less than the reference voltage, the sensing circuit outputs the sensing signal having the reset logic state;
if the switching voltage is less than the reference voltage, turning on the high-side switch, and controlling the sensing circuit to compare the switching voltage on the switching terminal with the reference voltage to determine whether the switching voltage is less than the reference voltage, wherein if the switching voltage is greater than the reference voltage, the sensing circuit outputs the sensing signal having the reset logic state; if the switching voltage is less than the reference voltage, the sensing circuit outputs the sensing signal having the set logic state;
if the switching voltage is greater than the reference voltage, turning off the high-side switch and the low-side switch, and controlling the sensing circuit to compare the switching voltage on the switching terminal with the reference voltage to determine whether the switching voltage is greater than the reference voltage, wherein if the switching voltage is greater than the reference voltage, the sensing circuit outputs the sensing signal having the set logic state; and if the switching voltage is less than the reference voltage, the sensing circuit outputs the sensing signal having the reset logic state.

17. The integrated circuit of claim 16, further comprising a current sensing circuit, wherein the control logic circuit is further configured to:
provide a current from the input terminal to the switching terminal and turn on the low-side switch, and
control the current sensing circuit to detect whether there is a current flows through the low-side switch,
wherein if it is detected that there is a current flows through the low-side switch, the current sensing circuit outputs a sensing signal having a reset logic state, and if no current is detected to flow through the low-side switch, the current sensing circuit outputs the sensing signal having the set logic state.
